(19) United States
(12) Patent Application Publication
(10) Pub. No.: US 2026/0136690 A1
(43) Pub. Date: May 14, 2026

(54) PHOTODETECTION DEVICE AND ELECTRONIC EQUIPMENT

(71) Applicant: SONY SEMICONDUCTOR SOLUTIONS CORPORATION, Kanagawa (JP)

(72) Inventor: Yoshiaki TASHIRO, Tokyo (JP)

(73) Assignee: SONY SEMICONDUCTOR SOLUTIONS CORPORATION, Kanagawa (JP)

(21) Appl. No.: 19/118,711

(22) PCT Filed: Sep. 25, 2023
(86) PCT No.: PCT/JP2023/034762

§ 371 Date: Apr. 4, 2025

(30) Foreign Application Priority Data
Oct. 28, 2022 (JP) 2022-173644

(51) Int. Cl. H10F 39/18; G01S 7/4913; G01S 17/34

(52) U.S. Cl. CPC H10F 39/1843; G01S 7/4913; G01S 17/34

(57) ABSTRACT

A light detecting device includes a first section including a first substrate, and the first substrate includes a compound semiconductor layer configured to convert light into an electrical signal. The light detecting device includes a second section including a second substrate, and a third section including a third substrate. The second substrate includes a first amplifying circuit that amplifies the electrical signal, and the third substrate includes a second amplifying circuit and a selection circuit. The first, second, and third sections are stacked with the second section being between the first section and the third section.

### CROSS REFERENCE TO RELATED APPLICATIONS

This application claims the benefit of Japanese Priority Patent Application JP 2022-173644 filed Oct. 28, 2022, the entire contents of which are incorporated herein by reference.

### TECHNICAL FIELD

The present technology (technology according to the present disclosure) relates to a photodetection device and electronic equipment, and in particular, to a photodetection device and electronic equipment including a layer of a compound semiconductor.

### BACKGROUND ART

In recent years, image sensors (infrared sensors) having sensitivity in an infrared region have been commercialized. For example, PTL 1 discloses a semiconductor element formed by laminating, by hybrid bonding, an element board including a compound semiconductor layer and a readout circuit board including a silicon layer in such a manner that wiring layer sides of the boards face each other.

### CITATION LIST

### Patent Literature

PTL 1: Japanese Patent Laid-open No. 2021-89978

### SUMMARY

At least one embodiment is directed to a light detecting device. The light detecting device includes a first section including a first substrate, and the first substrate includes a compound semiconductor layer configured to convert light into an electrical signal. The light detecting device includes a second section including a second substrate, and a third section including a third substrate. The second substrate includes a first amplifying circuit that amplifies the electrical signal, and the third substrate includes a second amplifying circuit and a selection circuit. The first, second, and third sections are stacked with the second section being between the first section and the third section. The first section further comprises an electrode that transfers the electric signal to the first amplifying circuit. The first section includes an insulating layer in which the electrode is disposed. The insulating layer is between the first substrate and the second substrate. The first amplifying circuit includes a transimpedance amplifier (TIA) circuit. The TIA circuit may be a capacitive TIA circuit comprising a feedback loop that includes a capacitance. The second amplifying circuit comprises an amplification transistor. The selection circuit comprises a selection transistor that receives output of the amplification transistor. The third substrate further comprises a holding circuit connected to the second amplifying circuit. The holding circuit comprises a sample and hold circuit. The sample and hold circuit comprises a first branch comprising a first capacitance and a second branch comprising a second capacitance. The first section further comprises a first insulating layer, the second section further comprises a second insulating layer and a third insulating layer on opposing sides of the second substrate, and the third section further comprises a fourth insulating layer. The first insulating layer and the second insulating layer contact one another at an interface between the first section and the second section. The third insulating layer and the fourth insulating layer contact one another at an interface between the second section and the third section.

At least one embodiment is directed to a light detecting device including a first section including a first substrate with the first substrate including a compound semiconductor layer configured to convert light into an electrical signal. The light detecting device includes a second section including a second substrate with the second substrate including a first amplifying circuit that amplifies the electrical signal. The light detecting device includes a third section including a third substrate with the third substrate including a sample and hold circuit. The first, second, and third sections are stacked with the second section being between the first section and the third section. The third section further comprises a second amplifying circuit and a selection circuit. The first amplifying circuit comprises a transimpedance amplifier (TIA) circuit and the second amplifying circuit comprises an amplification transistor. The first section further comprises an electrode that transfers the electric signal to the first amplifying circuit. The first section includes an insulating layer in which the electrode is disposed. At least one embodiment is directed to an electronic device that includes a light detecting device described herein and a signal processing circuit.

### Technical Problem

In the above-described semiconductor element, a plurality of layers of wiring are provided between the compound semiconductor layer and the silicon layer. It is therefore desirable to provide a photodetection device and electronic equipment for which effects of parasitic capacitance are suppressed.

### BRIEF DESCRIPTION OF DRAWINGS

FIG. 1 is a chip layout diagram depicting a configuration example of a photodetection device according to a first embodiment of the present technology.

FIG. 2 is a block diagram depicting a configuration example of the photodetection device according to the first embodiment of the present technology.

FIG. 3 is an equivalent circuit diagram of a pixel in the photodetection device according to the first embodiment of the present technology.

FIG. 4 is a longitudinal sectional view depicting a cross-sectional configuration of pixels in the photodetection device according to the first embodiment of the present technology.

FIG. 5 is a longitudinal sectional view depicting a cross-sectional configuration of pixels in a photodetection device according to a comparative example.

FIG. 6 is a block diagram depicting an example of a general configuration of electronic equipment according to the first embodiment of the present technology.

FIG. 7 is a block diagram depicting an example of a general configuration of electronic equipment according to a second embodiment of the present technology.

FIG. 8 is an equivalent circuit diagram of a pixel in a photodetection device according to the second embodiment of the present technology.

FIG. 9 is a block diagram depicting an example of schematic configuration of a vehicle control system.

FIG. 10 is a diagram of assistance in explaining an example of installation positions of an outside-vehicle information detecting section and an imaging section.

### DESCRIPTION OF EMBODIMENTS

Preferred modes for implementing the present technology will hereinafter be described with reference to the drawings. Note that the embodiments described below illustrate examples of a typical embodiment of the present technology and do not narrow interpretation of the scope of the present technology.

In the description of the drawings below, the same or similar components are denoted by the same or similar reference signs. However, note that the drawings are schematic and that the relation between thicknesses and planar dimensions, the ratio among thicknesses of layers, and the like are different from those in practice. Consequently, specific thicknesses and dimensions should be determined in consideration of the description below. In addition, needless to say, the drawings include portions with different dimensional relations and different ratios. Further, the drawings adopted are suitable for description of the present technology, and hence, there may be a difference in configuration between the drawings.

Moreover, the embodiments disclosed below illustrate devices and methods for embodying technical concepts of the present technology, and the technical concepts of the present technology do not limit the materials, shapes, structures, arrangements, and the like of the components to those described below. Variations can be made to the technical concepts of the present technology within the technical scope defined by the claims.

Further, the definition of directions such as up and down in the description below is merely for convenience of description and does not limit the technical concepts of the present disclosure. Needless to say, for example, when a target is observed after being rotated through 90°, up-down is converted into and read as left-right. When the target is observed after being rotated through 180°, up-down is inverted and read as down-up.

Description will be made in the following order.
1. First Embodiment
2. Second Embodiment
3. Third Embodiment

### Example of Application to Mobile Body

### First Embodiment

In the present embodiment, an example will be described in which the present technology is applied to a photodetection device corresponding to a back-illuminated CMOS (Complementary Metal Oxide Semiconductor) image sensor.

### Entire Configuration of Photodetection Device

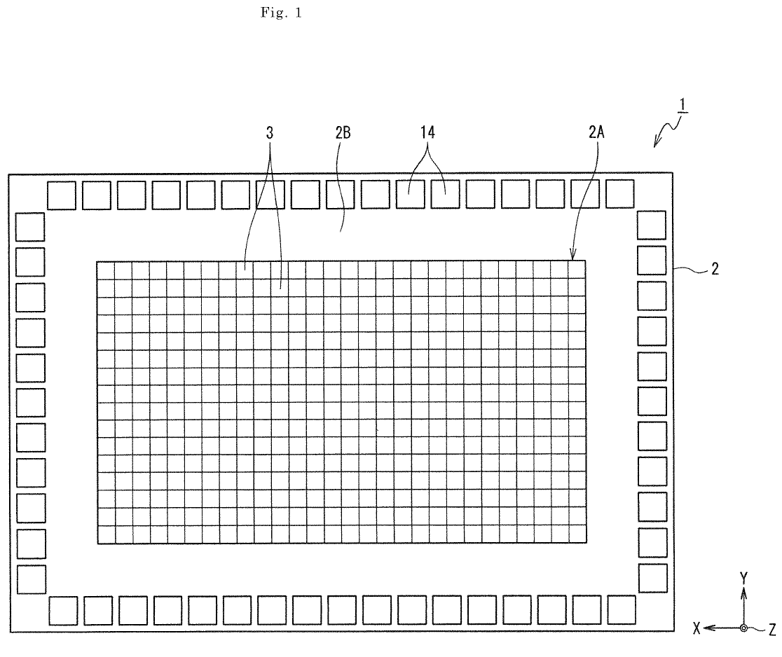

First, an entire configuration of a photodetection device 1 will be described. As illustrated in FIG. 1, the photodetection device 1 according to the first embodiment of the present technology mainly includes a semiconductor chip 2 having a quadrangular shape as a two-dimensional planar shape as seen in plan view. In other words, the photodetection device 1 is mounted on the semiconductor chip 2. As depicted in FIG. 6, the photodetection device 1 captures image light (incident light 106) from a subject via an optical system (optical lens) 102, converts the amount of the incident light 106 formed into an image on an imaging surface, into an electric signal on a per-pixel basis, and outputs the electric signal as a pixel signal.

As depicted in FIG. 1, the semiconductor chip 2 on which the photodetection device 1 is mounted includes, in a two-dimensional plane including an X direction and a Y direction that cross each other, a quadrangular pixel region 2A provided in a central portion and a peripheral region 2B provided outside the pixel region 2A in such a manner as to surround the pixel region 2A.

The pixel region 2A is, for example, a light receiving surface that receives light condensed by the optical system 102 depicted in FIG. 6. The pixel region 2A includes a plurality of pixels 3 arranged in a matrix form in a two-dimensional plane including the X direction and the Y direction. In other words, the pixels 3 are repeatedly arranged in each of the X direction and the Y direction that cross each other in the two-dimensional plane. Note that in the present embodiment, the X direction and the Y direction are orthogonal to each other as an example. Further, a Z direction (thickness direction, lamination direction) is a direction orthogonal to both the X direction and the Y direction. In addition, a horizontal direction is a direction perpendicular to the Z direction.

As depicted in FIG. 1, a plurality of bonding pads 14 are arranged in the peripheral region 2B. The plurality of bonding pads 14 are arranged, for example, along each of four sides of the two-dimensional plane of the semiconductor chip 2. Each of the plurality of bonding pads 14 is an input/output terminal used to electrically connect the semiconductor chip 2 to an external device.

### Logic Circuit

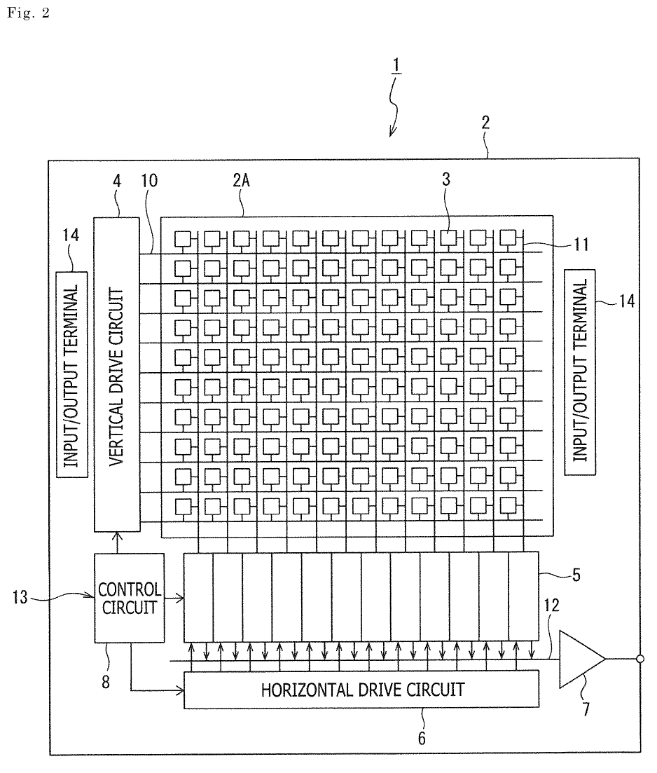

As depicted in FIG. 2, the semiconductor chip 2 includes a logic circuit 13. The logic circuit 13 includes a vertical drive circuit 4, column signal processing circuits 5, a horizontal drive circuit 6, an output circuit 7, a control circuit 8, and the like. The logic circuit 13 includes a CMOS (Complementary MOS) circuit including, as field effect transistors, an n-channel conductivity type MOSFET (Metal Oxide Semiconductor Field Effect Transistor) and a p-channel conductivity type MOSFET.

The vertical drive circuit 4 includes, for example, a shift register. The vertical drive circuit 4 sequentially selects a desired pixel drive line 10 and feeds a pulse for driving the pixels 3 to the selected pixel drive line 10, to thereby drive the pixels 3 on a per-row basis. In other words, the vertical drive circuit 4 sequentially selects and scans the pixels 3 in the pixel region 2A on a per-row basis in the vertical direction, and feeds, to the column signal processing circuits 5 through vertical signal lines 11, a pixel signal from each pixel 3 based on signal charge generated according to the amount of light received by a photoelectric conversion element of the pixel 3.

Each of the column signal processing circuits 5 is arranged, for example, for each column of the pixels 3 and executes signal processing such as noise removal on signals output from the pixels 3 in one row, on a per-pixel-column basis. For example, the column signal processing circuit 5 executes signal processing such as CDS (Correlated Double Sampling) and AD (Analog Digital) conversion to remove pixel-specific fixed pattern noise. A horizontal selection switch (not illustrated) is provided between and connected to an output stage of the column signal processing circuit 5 and a horizontal signal line 12.

The horizontal drive circuit 6 includes, for example, a shift register. The horizontal drive circuit 6 sequentially outputs horizontal scanning pulses to the column signal processing circuits 5 to select each of the column signal processing circuits 5 in order, and causes each of the column signal processing circuits 5 to output, to the horizontal signal line 12, the pixel signal subjected to signal processing.

The output circuit 7 executes signal processing on the pixel signals sequentially fed from the respective column signal processing circuits 5 through the horizontal signal line 12 and outputs the processed pixel signals. The signal processing may include, for example, buffering, black level adjustment, column variation correction, various digital signal processing operations, and the like.

On the basis of a vertical synchronization signal, a horizontal synchronization signal, and a master clock signal, the control circuit 8 generates clock signals and control signals used as references for operations of the vertical drive circuit 4, the column signal processing circuits 5, the horizontal drive circuit 6, and the like. The control circuit 8 then outputs the clock signals and control signals thus generated to the vertical drive circuit 4, the column signal processing circuits 5, the horizontal drive circuit 6, and the like.

### Pixel

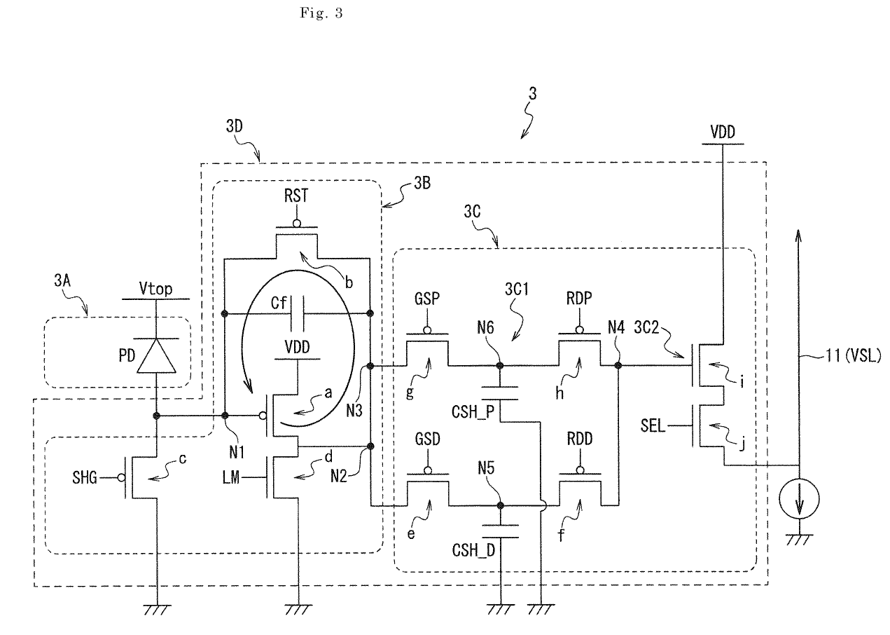

FIG. 3 is an equivalent circuit diagram depicting a configuration example of the pixel 3. The pixel 3 includes a circuit 3A, a circuit 3B succeeding the circuit 3A and connected to the circuit 3A, and a circuit 3C succeeding the circuit 3B and connected to the circuit 3B. The circuit 3B and the circuit 3C are included in a readout circuit 3D to which a photocurrent is input from the circuit 3A and from which a pixel signal can be output. In addition, the example of the readout circuit 3D depicted in FIG. 3 includes both PMOS transistors and NMOS transistors. When a negative voltage equal to or lower than a threshold voltage is applied to a gate electrode of a PMOS transistor, an inversion layer of holes is formed on an oxide film interface to electrically connect a source and a drain. When a positive voltage equal to or higher than a threshold voltage is applied to a gate electrode of an NMOS transistor, an inversion layer of electrons is formed on an oxide film interface to electrically connect a source and a drain. For both the PMOS transistor and the NMOS transistor, an on state refers to a state in which the source and the drain are electrically connected, and an off state refers to a state in which the source and the drain are not electrically connected.

The circuit 3A includes a photoelectric conversion element PD. The photoelectric conversion element PD generates signal charge according to the amount of light received. The photoelectric conversion element PD is connected on a cathode side thereof to a power supply line Vtop and on an anode side thereof to an input end of the circuit 3B. The photoelectric conversion element PD may be, for example, a photodiode. The circuit 3A outputs signal charge as a photocurrent from the anode size corresponding to an output end.

The input end of the circuit 3B (first circuit) is connected to the output end of the circuit 3A, and a photocurrent from the circuit 3A is input to the input end of the circuit 3B. The circuit 3B is an amplifying circuit and may be referred to herein as such. Specifically, the circuit 3B may comprise an impedance modulation (Trans Impedance Amplifier, TIA) circuit that amplifies a photocurrent generated in the photoelectric conversion element PD and that outputs a voltage signal from an output end. In the present embodiment, the voltage output by the circuit 3B is referred to as a voltage signal. Note that the voltage signal is unlikely to be affected by parasitic capacitance. In the present embodiment, an example will be described in which the circuit 3B is a capacitive TIA circuit comprising a feedback loop with a capacitance (e.g., Cf). In more detail, the circuit 3B may include a CTIA (Capacitive Trans Impedance Amplifier) circuit. The CTIA circuit is an impedance modulation circuit that utilizes feedback capacitance Cf described below to amplify the photocurrent. Note that the circuit 3B depicted in FIG. 3 is an example of the CTIA circuit.

The circuit 3B includes transistors “a” to “c” that are PMOS transistors, a transistor “d” that is an NMOS transistor, and the feedback capacitance Cf. The transistors “a” to “d”′ correspond to examples of a first transistor. The anode side of the photoelectric conversion element PD is connected to a gate of the transistor “a” via a node N1 of the circuit 3B. A source of the transistor “a” is connected to a power supply line VDD, and a drain of the transistor “a” is connected to a node N2 of the circuit 3B and to a drain of the transistor “d.” The transistor “b” has a source connected to the node N2 and a drain connected to the node N1. The feedback capacitance Cf is parasitic capacitance present between the source and drain of the transistor “b,” that is, between the node N1 and the node N2. A source of the transistor “d” is connected to a reference potential line (for example, a low voltage line). A source of the transistor “c” is connected to the anode side of the photoelectric conversion element PD, and a drain of the transistor “c” is connected to the reference potential line (for example, a low voltage line).

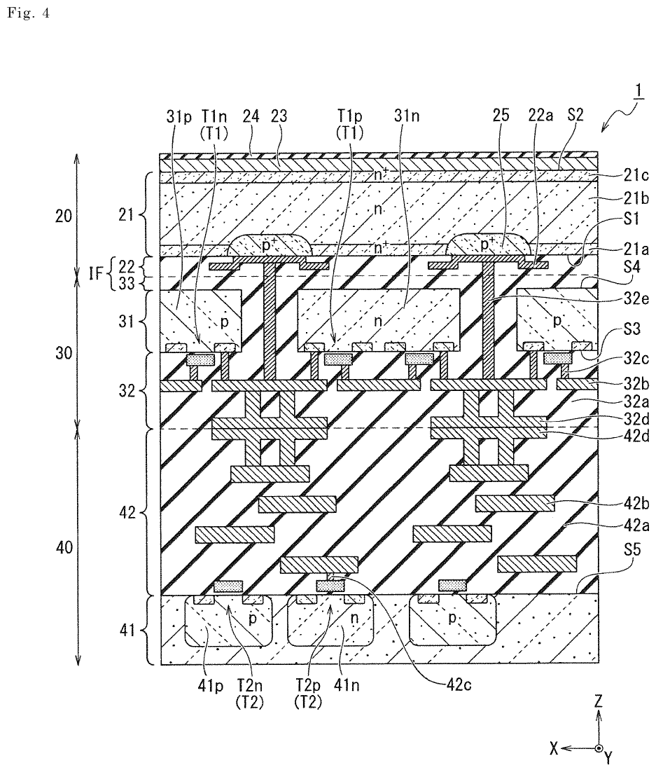

The circuit 3B receives, at an input end, a photocurrent generated by the photoelectric conversion element PD. Then, the circuit 3B inputs the received photocurrent to the gate of the transistor “a,” corresponding to an amplifying element, and loops (causes feedback of) the current between the transistor “a” and the transistor “b” as depicted by an arrow in FIG. 4 to increase a gain for amplification. More specifically, when signal charge generated by the photoelectric conversion element PD is accumulated in the node N1 of the circuit 3B, the gate voltage of the transistor “a” changes. Then, according to the changed gate voltage, a voltage is output to the node N2 through the transistor “a.” The transistor “a,” corresponding to an amplifying element, is of an inversion amplification type, and acts to reduce the output voltage when the gate voltage increases. Then, the amount of change in output voltage returns to the node N1 through the feedback capacitance Cf. In other words, as for the voltage of the node N1 and the voltage of the node N2, the voltage of the node N1 is maintained, and the voltage of the node N2 changes. Accordingly, feedback is performed in such a manner that the amount of change in voltage of the node N2 increases as the amount of signal charge generated in the photoelectric conversion element PD increases.

How much the voltage of the node N2 changes depends on an efficiency of the feedback, and the efficiency of the feedback depends on the feedback capacitance Cf. In other words, an amplification factor of the circuit 3B depends on the feedback capacitance Cf. In general, in a case where the charge of one signal charge is denoted as Q, the voltage is denoted as V, and the feedback capacitance is denoted as Cf, the signal charge Q is converted into voltage in accordance with V=Q/Cf. On the basis of this equation, when the feedback capacitance Cf is reduced, the voltage V obtained increases, and sensitivity of the circuit 3B can thus increase. The feedback capacitance Cf is designed as an aggregation of parasitic capacitance. More specifically, the feedback capacitance Cf is designed as an aggregation of parasitic capacitance mainly generated between wires. The circuit 3B outputs a voltage signal thus obtained, from the node N2 and a node N3 as a voltage signal.

In addition, the transistors “b” to “d” are fed with drive signals RST, LM, and SHG from the vertical drive circuit 4 (FIG. 1) via the plurality of pixel drive lines 10. The transistor “b” is turned on to reset the feedback capacitance Cf. The transistor “d” is turned on to reset potential of the node N2, and the transistor “c” is turned on to reset the photoelectric conversion element PD.

The circuit 3C (second circuit) includes a voltage holding circuit 3C1 (also called a holding circuit 3C1) for holding the voltage signal from the circuit 3B and a source follower circuit 3C2 (also called an amplifying circuit 3C2) that succeeds and is connected to the voltage holding circuit 3C1 and that outputs a pixel signal. The voltage holding circuit 3C1 is, for example, a sample hold circuit. Note that FIG. 3 depicts an example of the voltage holding circuit 3C1, that is, the sample hold circuit, and an example of the source follower circuit 3C2. Input ends of the circuit 3C, that is, two input ends of the voltage holding circuit 3C1, are connected to the node N2 and the node N3 corresponding to the output ends of the circuit 3B. The voltage signal from circuit 3B is input to the two input ends of the voltage holding circuit 3C1.

The voltage holding circuit 3C1 may comprise a first branch including a first capacitance CSH_P and transistors g and h, and a second branch including a second capacitance CSH_D and transistors e and f. In more detail, the voltage holding circuit 3C1 includes transistors “e” to “h” corresponding to PMOS transistors, and capacitors CSH_D and CSH_P capable of holding a voltage signal. CSH_D and the capacitor CSH_P are examples of a first capacitor. The transistor “e” has a source connected to the node N2 and a drain connected to a source of the transistor “f” via a node N5 of the circuit 3C. A drain of the transistor “f” is connected to a node N4 of the circuit 3C. The capacitor CSH_D is provided between the node N5 and a reference potential. The transistor “g” has a source connected to the node N3 and a drain connected to a source of the transistor “h” via a node N6 of the circuit 3C. A drain of the transistor “h” is connected to the node N4. The capacitor CSH_P is provided between the node N5 and the reference potential.

The source follower circuit 3C2 succeeds the voltage holding circuit 3C1 and is connected to the voltage holding circuit 3C1 via the node N4. The source follower circuit 3C2 includes transistors “i” and “j” corresponding to NMOS transistors. The transistor “i” is an amplifying element (also called an amplification transistor), and the transistor “j” is a selection transistor (also called a selection circuit). The transistors “e” to “j” correspond to examples of a second transistor.

The transistors “e” to “h” and the transistor “j” are fed with drive signals GSD, RDD, GSP, RDP, and SEL from the vertical drive circuit 4 (FIG. 1) via the plurality of pixel drive lines 10. With the transistor “f” off, the transistor “e” is turned on to hold the voltage signal from the circuit 3B in the capacitor CSH_D via the node N2. With the transistor “e” off, the transistor “f” is turned on to feed the voltage signal held in the capacitor CSH_D to a gate of the transistor “i” via the node N4. Similarly, with the transistor “h” off, the transistor “g” is turned on to hold the voltage signal from the circuit 3B in the capacitor CSH_P via the node N3. With the transistor “g” off, the transistor “h” is turned on to feed the voltage signal held in the capacitor CSH_P to the gate of the transistor “i” via the node N4. The source follower circuit 3C2 outputs a pixel signal indicating a level corresponding to the voltage signal fed via the node N4. The output pixel signal is fed to the column signal processing circuits 5 via the vertical signal lines 11 (VSLs).

Note that each of the above-described transistors includes, for example, a MOSFET having a gate insulating film formed by a silicon oxide film (SiO₂ film), a gate electrode, and a pair of main electrode regions functioning as a source region and a drain region. Alternatively, these transistors may each be a MISFET (Metal Insulator Semiconductor FET) having a gate insulating film formed by a silicon nitride film (Si₃N₄ film) or a laminated film including a silicon nitride film, a silicon oxide film, or the like.

### Specific Configuration of Photodetection Device

Now, a specific configuration of the photodetection device 1 will be described with reference to FIGS. 1 and 4. Note that FIG. 4 depicts only portions where the pixels 3 are present.

### Laminated Structure of Photodetection Device

As depicted in FIG. 4, the photodetection device 1 (semiconductor chip 2) has a three-layer laminated structure including a light receiving board section 20 (also called a section 20) as a first semiconductor base, a first circuit board section 30 (also called a section 30) as a second semiconductor base, and a second circuit board section 40 (also called a section 40) as a third semiconductor base, the light receiving board section 20, the first circuit board section 30, and the second circuit board section 40 being laminated in this order. The circuit 3A is provided in the light receiving board section 20. The readout circuit 3D is formed mainly in the first circuit board section 30 and the second circuit board section 40. More specifically, as for the circuits 3B and 3C included in the readout circuit 3D, the circuit 3B is formed mainly in the first circuit board section 30, and the circuit 3C is formed mainly in the second circuit board section 40.

### Light Receiving Board Section (First Semiconductor Base)

As depicted in FIG. 4, the light receiving board section 20 has a laminated structure including, in the pixel region 2A, a protect film 24, a second electrode 23, a first semiconductor layer 21 (also called a substrate or semiconductor substrate 21) having a first surface S1 and a second surface S2 positioned opposite to each other in a thickness direction (Z direction), and a first insulating layer 22, the protect film 24, the second electrode 23, the first semiconductor layer 21, and the first insulating layer 22 being laminated in this order. The first circuit board section 30 is provided with the first insulating layer 22 on the first surface S1 side and with the protect film 24 and the second electrode 23 on the second surface S2 side.

Each of the first insulating layer 22 and the first semiconductor layer 21 has a quadrangular shape as a two-dimensional planar shape. The first semiconductor layer 21 is provided mainly in the pixel region 2A (see FIG. 1), and a contour of the first semiconductor layer 21 as seen in plan view is positioned inside a contour of the first insulating layer 22. On the other hand, the first insulating layer 22 is provided over the pixel region 2A and the peripheral region 2B (see FIG. 1) as seen in plan view, and a portion of the first insulating layer 22 positioned around the first semiconductor layer 21 has a larger thickness than a portion of the first insulating layer 22 overlapping the first semiconductor layer 21. The first insulating layer 22 has, for example, a multilayer structure including insulating material films such as a silicon oxide (SiO₂) film, a silicon nitride (Si₃N₄) film, and a silicon carbide (SiC) film but is not limited to this. The first insulating layer 22 is provided with a first electrode 22a. As depicted in FIG. 4, the first electrode 22a is an electrode (anode) to which a voltage used to read out signal charge (holes or electrons; in the description below, the signal charge is assumed to be holes for convenience) generated in a photoelectric conversion layer 21b described below is fed, and is provided for each pixel 3. The first electrode 22a is in contact with a diffusion region 25 described below. The first electrode 22a includes, for example, tungsten but is not limited to this. The first electrode 22a may correspond to at least part of a transfer electrode that transfers the electrical signal generated by the photoelectric conversion layer 21b to an amplifying circuit (e.g., circuit 3B).

In the first semiconductor layer 21, the photoelectric conversion element PD of the circuit 3A is formed for each pixel 3. As depicted in FIG. 4, the first semiconductor layer 21 has a laminated structure including a first contact layer 21a, the photoelectric conversion layer 21b, and a second contact layer 21c laminated in this order from the first surface S1 side. The first contact layer 21a, the photoelectric conversion layer 21b, and the second contact layer 21c are provided in all the pixels 3 in common and have substantially the same planar shape. The first contact layer 21a faces the first surface S1, and the second contact layer 21c faces the second surface S2.

The first contact layer 21a is a compound semiconductor layer of a first conductivity type. Dark current can be suppressed by using, as the first contact layer 21a, a material having a larger band gap than the semiconductor material of the photoelectric conversion layer 21b. In the description of the present embodiment, the first contact layer 21a is assumed to be an n-type semiconductor layer including InP (indium phosphide). The first contact layer 21a is provided with the diffusion region 25 for each pixel 3. The diffusion region 25 is a semiconductor region of a second conductivity type different from the first conductivity type. In the description of the present embodiment, the diffusion region 25 is assumed to be a p-type semiconductor layer into which impurities of, for example, Zn (zinc) or the like are doped. The diffusion regions 25 are spaced apart from one another along the horizontal direction, and are each in contact with the first electrode 22a at the first surface S1 in the thickness direction. The diffusion region 25 is provided to read out, for each pixel 3, signal charge generated in the photoelectric conversion layer 21b. A pn bonding interface is formed between the diffusion region 25 of the second conductivity type and the n-type first contact layer 21a to electrically separate the adjacent pixels 3 from each other.

As for the first surface S1 and the second surface S2, the photoelectric conversion layer 21b photoelectrically converts light incident from the side of the second surface S2. The photoelectric conversion layer 21b absorbs light of a predetermined wavelength, infrared light in the present embodiment, to generate signal charge. Infrared light is, for example, short wave infrared (SWIR) light. The photoelectric conversion layer 21b is a semiconductor layer including a material of, for example, Ge (germanium), quantum (Q) dots, a compound semiconductor, or the like. The compound semiconductor includes, for example, a group III-V semiconductor or the like. For the group III-V semiconductor, compound semiconductor materials include, for example, InGaAs (indium gallium arsenic), InAsSb (indium arsenic antimony), InAs (indium arsenic), InSb (indium antimony), HgCdTe (mercury cadmium telluride), and the like. In the description of the present embodiment, the photoelectric conversion layer 21b is assumed to be formed by an n-type InGaAs (indium gallium arsenic) layer but may alternatively be an i-type InGaAs layer.

The second contact layer 21c is a compound semiconductor layer of the first conductivity type. In the description of the present embodiment, the first contact layer 21a is assumed to be an n-type semiconductor layer including InP (indium phosphide). Note that a light absorptivity of the compound semiconductor of the second contact layer 21c varies according to wavelengths. Accordingly, adjustment of film thickness of the second contact layer 21c allows light in a desired wavelength band to be transmitted to the photoelectric conversion layer 21b. For example, to allow light of a wavelength in a visible region to be transmitted to the photoelectric conversion layer 21b, the second contact layer 21c preferably has a thickness of, for example, 5 to 300 nm. The above-described range of the film thickness is based on such a definition that visible light can be transmitted when the second contact layer (InP) has an absorptivity of 0% or more but 90% or less for a wavelength of 600 nm. In a case where the light transmitted to the photoelectric conversion layer 21b may exclusively be light of a wavelength in a short infrared region, it is sufficient if the second contact layer 21c is, for example, from 5 nm to 750 μm in thickness. As described above, adjustment of the thickness of the second contact layer 21c enables the photoelectric conversion layer 21b to photoelectrically convert light of a desired wavelength within a range from light of a wavelength in the short infrared region to a wavelength in the visible region.

In addition, a light absorptivity of the photoelectric conversion layer 21b also varies according to wavelengths. Accordingly, in a case where the photoelectric conversion layer 21b photoelectrically converts, for example, blue light of a wavelength of 400 nm as light in the visible region, the photoelectric conversion layer 21b preferably has a thickness of, for example, 100 nm or more. In a case where the photoelectric conversion layer 21b photoelectrically converts light of a wavelength in the short infrared region, the photoelectric conversion layer 21b preferably has a thickness of, for example, 3 μm or more.

For example, as an electrode common to the pixels P, the second electrode 23 is provided on the second contact layer 21c (light incident side) in contact with the second contact layer 21c. The second electrode 23 is used to discharge that portion of the charge generated in the photoelectric conversion layer 21b which is not used as signal charge (cathode). For example, in a case where holes are read out, as signal charge, from the first electrode 22a described below, for example, electrons can be discharged through the second electrode 23. The second electrode 23 is formed by, for example, a conductive film through which incident light such as infrared light can be transmitted. The second electrode 23 may include, for example, ITO (Indium Tin Oxide), ITiO (In₂O₃—TiO₂), or the like. In addition, the second electrode 23 is electrically connected to, for example, the bonding pads 14 (see FIG. 1) via holes provided in the peripheral region 2B. The protect film 24 is laminated on the second electrode 23, and includes, for example, silicon nitride but is not limited to this.

### First Circuit Board Section (Second Semiconductor Base)

As depicted in FIG. 4, the first circuit board section 30 has a laminated structure including a second insulating layer 33, a second semiconductor layer 31 (also called a substrate or semiconductor substrate 31) having a third surface S3 and a fourth surface S4 positioned opposite to each other in the thickness direction (Z direction), and a first wiring layer 32, the second insulating layer 33, the second semiconductor layer 31, and the first wiring layer 32 being laminated in this order. The first wiring layer 32 is provided on the third surface S3 side of the second semiconductor layer 31, and the second insulating layer 33 is provided on the fourth surface S4 side of the second semiconductor layer 31. In addition, a surface of the second insulating layer 33 opposite to the second semiconductor layer 31 side is joined to the first insulating layer 22.

The second insulating layer 33 includes a known insulating material. The second insulating layer 33 includes, for example, silicon oxide but is not limited to this. Note that the first insulating layer 22 and the second insulating layer 33 described above may collectively be referred to as an insulating layer IF. The circuit 3B (also called an amplifying circuit) is provided within the three layers ranging from the insulating layer IF to the first wiring layer 32.

All of the first transistors included in the circuit 3B are provided in the second semiconductor layer 31. FIG. 4 illustrates an NMOS transistor T1n and a PMOS transistor T1p provided in the second semiconductor layer 31. In a case where the NMOS transistor T1n and the PMOS transistor T1p are not distinguished from each other, the NMOS transistor T1n and the PMOS transistor T1p are each simply referred to as a transistor T1. Note that FIG. 4 illustrates how the wires and the first transistors of the circuit 3B are formed in the photodetection device 1, and may include a portion that is inconsistent with the circuit configuration of the circuit 3B in practice. As for the third surface S3 and the fourth surface S4, the first transistors are provided at a position closer to the third surface S3 in the thickness direction of the second semiconductor layer 31. In other words, of the third surface S3 and the fourth surface S4, the third surface S3 side is provided with a gate electrode of the transistor T1. The third surface S3 is a surface on the first wiring layer 32 side of the second semiconductor layer 31. The second semiconductor layer 31 includes a p-type well region 31p and an n-type well region 31n at different positions as seen in plan view. The NMOS transistor Tin is provided in the p-type well region 31p, and the PMOS transistor T1p is provided in the n-type well region 31n.

The first wiring layer 32 includes an insulating film 32a, a wire 32b, a first conductor 32c, and a connection pad 32d. The insulating film 32a includes a known insulating material such as silicon oxide, for example. The wire 32b is a first wire, and is provided in the first wiring layer 32 and extends along the horizontal direction. In the first wiring layer 32, only one layer of the wire 32b is provided along the thickness direction. In addition, by dividing one layer of film including one conductive material into pieces by using a known damascene process or a known lithography technology, a known etching technology, and the like, the wire 32b is provided as a plurality of wires spaced apart from one another along the horizontal direction. The wire 32b and the connection pad 32d extend along the horizontal direction. Extension along the horizontal direction indicates, as to the horizontal direction and the thickness direction, extension mainly along the horizontal direction. The wire 32b is one of the wires that are provided in the first wiring layer 32 and extend along the horizontal direction, the one being positioned closest to the second semiconductor layer 31 in the thickness direction of the first wiring layer 32. The first conductor 32c is provided in the first wiring layer 32 and extends along the thickness direction of the first wiring layer 32. Extension along the thickness direction indicates, as to the horizontal direction and the thickness direction, extension mainly along the thickness direction. The first conductor 32c is a via (contact) penetrating, in the thickness direction, the insulating film 32a provided between the transistor T1 and the wire 32b to connect the transistor T1 of the second semiconductor layer 31 to the wire 32b. More specifically, to form the circuit 3B, the first conductor 32c is connected to any of the gate electrode, source, drain, and the like of the transistor T1 at one end thereof in the thickness direction, and to the wire 32b at the other end thereof.

The circuit 3B includes the wire 32b and the first conductor 32c as wiring portions. The circuit 3B may include a plurality of the wires 32b and a plurality of the first conductors 32c. In addition, the circuit 3B includes a second conductor 32e as a wiring portion. For example, one second conductor 32e is provided for each pixel 3. The second conductor 32e extends along the thickness direction of the second semiconductor layer 31. Moreover, the second conductor 32e penetrates the second semiconductor layer 31 in the thickness direction to connect the photoelectric conversion element PD to the wire 32b. The second conductor 32e is connected to the first electrode 22a at one end thereof in the extension direction and to the wire 32b at the other end thereof. The second conductor 32e and the second semiconductor layer 31 are insulated from each other by a known insulating film. The second conductor 32e is formed over the insulating layer IF, the second semiconductor layer 31, and the first wiring layer 32. Further, the circuit 3B includes parasitic capacitance as the feedback capacitance Cf. The parasitic capacitance occurs mainly in association with the wire 32b.

The connection pad 32d is a first connection pad. The connection pad 32d is laminated on the wire 32b via the insulating film 32a and faces a surface of the first wiring layer 32 on the second circuit board section 40 side. The connection pad 32d is electrically connected to the circuit 3B, and more specifically, to the wire 32b of the circuit 3B. The connection pad 32d is formed, for example, by a dual damascene process but is not limited to this. The connection pad 32d is joined to a connection pad 42d described below. The connection pad 32d and the connection pad 42d are joined together to electrically connect the circuit 3B and the circuit 3C.

The wire 32b and the connection pad 32d include metal. Examples of the metal that are used for the wire 32b and the connection pad 32d include copper (Cu), aluminum (Al), and the like. The first conductor 32c and the second conductor 32e include metal. Examples of the metal used for the first conductor 32c and the second conductor 32e include tungsten (W), ruthenium (Ru), and the like.

### Second Circuit Board Section (Third Semiconductor Base)

As depicted in FIG. 4, the second circuit board section 40 has a laminated structure including a second wiring layer 42 and a third semiconductor layer 41 (also called a substrate or a semiconductor substrate) laminated in this order. A surface of the second wiring layer 42 opposite to the third semiconductor layer 41 side is joined to the first wiring layer 32. A surface of the third semiconductor layer 41 on the second wiring layer 42 side is a fifth surface S5. The circuit 3C is provided within the two layers ranging from the second wiring layer 42 to the third semiconductor layer 41.

All of the second transistors included in the circuit 3C are provided in the third semiconductor layer 41. FIG. 4 illustrates an NMOS transistor T2n and a PMOS transistor T2p provided in the third semiconductor layer 41. In a case where the NMOS transistor T2n and the PMOS transistor T2p are not distinguished from each other, the NMOS transistor T2n and the PMOS transistor T2p are each simply referred to as a transistor T2. Note that FIG. 4 illustrates how the wires and the transistors of the circuit 3C are formed in the photodetection device 1, and may include a portion that is inconsistent with the circuit configuration of the circuit 3C in practice. The transistors T2 are provided for each pixel 3 on the fifth surface S5 side of the third semiconductor layer 41. The third semiconductor layer 41 includes a p-type well region 41p and an n-type well region 41n at different positions as seen in plan view. The NMOS transistor T2n is provided in the p-type well region 41p, and the PMOS transistor T2p is provided in the n-type well region 41n.

The second wiring layer 42 includes an insulating film 42a, a wire 42b, a third conductor 42c, and the connection pad 42d. In addition, the second wiring layer 42 is provided with capacitors (not illustrated) as the first capacitor. The insulating film 42a includes a known insulating material such as silicon oxide, for example. The wire 42b is provided in the second wiring layer 42 and extends along the horizontal direction. In the second wiring layer 42, a plurality of layers of the wire 42b may be provided along the thickness direction. Further, by dividing one layer of film including one conductive material into pieces by using a known damascene process or a known lithography technology, a known etching technology, and the like, the wire 32b belonging to the same layer is provided as a plurality of wires spaced apart from one another along the horizontal direction. The wire 42b and the connection pad 42d extend along the horizontal direction. The third conductor 42c is provided in the second wiring layer 42 and extends along the thickness direction of the second wiring layer 42. The third conductor 42c is a via (contact) penetrating, in the thickness direction, the insulating film 42a provided between the transistor T2 and the wire 32b to connect the transistor T2 of the third semiconductor layer 41 to the wire 42b. More specifically, to form the circuit 3C, the third conductor 42c connects the gate electrode of the transistor T2 or a diffusion region such as the source or drain of the transistor T2 to the wire 32b. In addition, to form the circuit 3C, the third conductor 42c is a via penetrating, in the thickness direction, the insulating film 42a provided between the wires 42b to connect the wires 42b, though this is not illustrated. Note that the dual damascene process may be used to form the wires 42b and to cause the wires 42b to be connected together.

The circuit 3C includes the wire 42b and the third conductor 42c as wiring portions. The circuit 3C may include a plurality of the wires 42b and a plurality of the third conductors 42c. In addition, the circuit 3C includes the first capacitor such as the capacitor CSH_D and the capacitor CSH_P. The first capacitor is a capacitor having a MIM (Metal Insulator Metal) structure including an insulator sandwiched by metal and may be, for example, a capacitor having a three-dimensional MIM (3DMIM) structure with a larger capacity.

The connection pad 42d is a second connection pad. The connection pad 42d is laminated on the wire 42b via the insulating film 42a and faces the surface of the second wiring layer 42 on the first circuit board section 30 side. The connection pad 42d is electrically connected to the circuit 3C, and more specifically, to the wire 42b of the circuit 3C. The connection pad 42d is formed, for example, by the dual damascene process but is not limited to this. The connection pad 42d is joined to the connection pad 32d described above, thus connecting the circuits 3B and 3C.

The wire 42b and the connection pad 42d include metal. Examples of the metal used for the wire 42b and the connection pad 42d may include copper (Cu), aluminum (Al), and the like. The third conductor 42c includes metal. Examples of the metal used for the third conductor 42c may include tungsten (W), ruthenium (Ru), and the like.

### Main Effects of First Embodiment

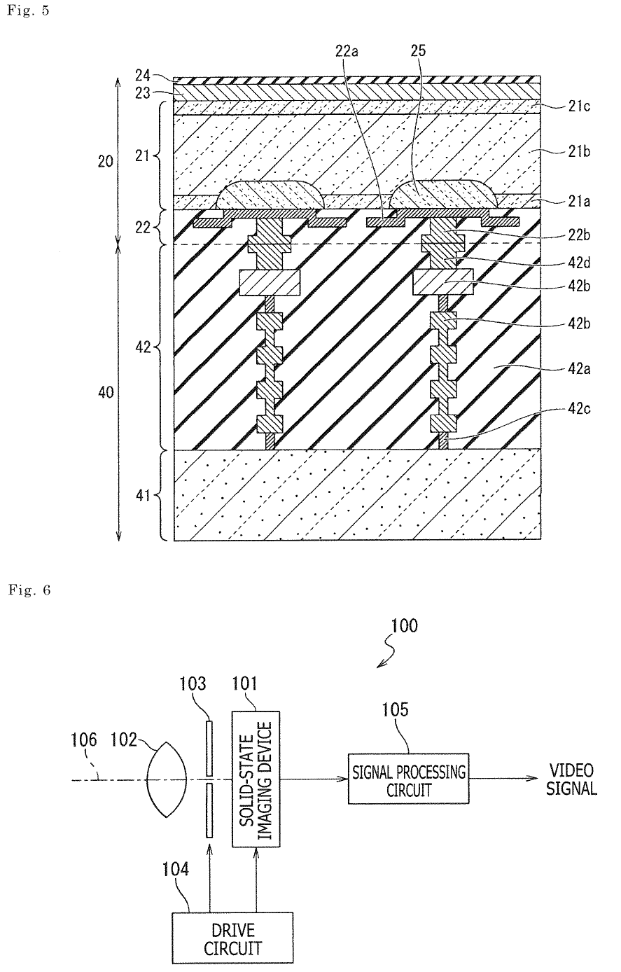

Main effects of the first embodiment will be described below. However, before the description of the main effects, a comparative example will be described. FIG. 5 depicts a photodetection device according to a comparative example. The photodetection device does not include the first circuit board section 30 and has a laminated structure of only two layers of the light receiving board section 20 and the second circuit board section 40. Since the photodetection device in the comparative example does not include the first circuit board section 30, the entire readout circuit 3D is provided in the second circuit board section 40. A plurality of wires 42b and a plurality of connection pads 22b and 42d are interposed between the photoelectric conversion element PD and the circuit 3B of the readout circuit 3D along the thickness direction, and parasitic capacitance is generated according to the number of layers of the wires 42b and the connection pads 22d and 42d. More specifically, at the output end of the photoelectric conversion element PD, parasitic capacitance is generated according to the number of layers of the wires and the like. The feedback capacitance Cf of the circuit 3B increases as the parasitic capacitance increases. Increasing feedback capacitance Cf reduces the efficiency of the feedback, reducing the output voltage signal.

In contrast, the photodetection device 1 according to the first embodiment of the present technology has a laminated structure including the first semiconductor layer 21, the insulating layer IF, the second semiconductor layer 31, the first wiring layer 32, the second wiring layer 42, and the third semiconductor layer 41 laminated in this order, the first semiconductor layer 21 including the layer of the compound semiconductor and being provided with the photoelectric conversion element PD, the insulating layer IF including the insulating material, the second semiconductor layer 31 including silicon, and the third semiconductor layer 41 including silicon. The photodetection device 1 is equipped with the readout circuit 3D to which a photocurrent from the photoelectric conversion element PD is input and from which a pixel signal can be output. The readout circuit 3D includes the circuit 3B corresponding to the impedance modulation circuit that amplifies the photocurrent and outputs a voltage signal from an output end, and the circuit 3C having an input end connected to the output end of the circuit 3B. The circuit 3B is provided within the three layers ranging from the insulating layer IF to the first wiring layer 32. The circuit 3C is provided within the two layers ranging from the second wiring layer 42 to the third semiconductor layer 41.

As described above, in the first embodiment of the present technology, the second semiconductor layer 31 and the second wiring layer 42 are added to the photodetection device 1, and the circuit 3B corresponding to the impedance modulation circuit is provided for the added second semiconductor layer 31 and second wiring layer 42, and the insulating layer IF. This enables suppression of the number of layers of wire interposed between the photoelectric conversion element PD and the circuit 3B, allowing the parasitic capacitance of the impedance modulation circuit to be restrained from being increased. Accordingly, it is possible to suppress a reduction in voltage signal and to suppress a reduction in sensitivity of the circuit 3B. In addition, it is possible to suppress a reduction in efficiency of transferring a current generated in the photoelectric conversion element PD and to suppress a reduction in current gain.

Further, in the photodetection device 1 according to the first embodiment of the present technology, the circuit 3B utilizes the feedback capacitance Cf to amplify the photocurrent. This enables suppression of the number of layers of wire interposed between the photoelectric conversion element PD and the circuit 3B, thus allowing suppression of an increase in parasitic capacitance, suppression of an increase in feedback capacitance Cf, suppression of a reduction in voltage signal, and suppression of a reduction in sensitivity of the circuit 3B.

In addition, in the photodetection device 1 according to the first embodiment of the present technology, the circuit 3C includes the first capacitor capable of holding the voltage signal. Since the circuit 3C is provided in the circuit board section different from that in which the circuit 3B is provided, even with a large capacity of the first capacitor of the circuit 3C, the effects on the parasitic capacitance of the impedance modulation circuit can be suppressed. Accordingly, the first capacitor of the circuit 3C can be provided with a large capacity, allowing suppression of an increase in kTC noise in the circuit 3C. Note that the kTC noise is a range of motion within which signal charge is in motion due to heat.

Moreover, in the photodetection device 1 according to the first embodiment of the present technology, the first transistors included in the circuit 3B are provided in the second semiconductor layer 31. Of the second semiconductor layer 31 and the third semiconductor layer 41, the second semiconductor layer 31 is provided with the first transistors of the circuit 3B. This enables suppression of the number of layers of wire interposed between the photoelectric conversion element PD and the circuit 3B, thus allowing suppression of an increase in parasitic capacitance of the impedance modulation circuit, suppression of a reduction in voltage signal, and suppression of a reduction in sensitivity of the circuit 3B.

Further, in the photodetection device 1 according to the first embodiment of the present technology, the first transistors are provided at a position in the second semiconductor layer 31 closer to the first wiring layer 32, and the circuit 3B includes the wire 32b corresponding to the first wire that is provided in the first wiring layer 32 and extends along the horizontal direction, the first conductor 32c that is provided in the first wiring layer 32 and extends along the thickness direction to connect the first transistor to the wire 32b, and the second conductor 32e that penetrates the second semiconductor layer 31 in the thickness direction and connects the photoelectric conversion element PD to the wire 32b. Compared to a case where the first transistors are positioned closer to the insulating layer IF in the second semiconductor layer 31, the configuration as described above enables a reduction in the number of layers of the wire 32b, thus allowing suppression of an increase in parasitic capacitance of the impedance modulation circuit, suppression of a reduction in voltage signal, and suppression of a reduction in sensitivity of the circuit 3B.

In addition, in the photodetection device 1 according to the first embodiment of the present technology, the wire 32b corresponding to the first wire is one of the wires that are provided in the first wiring layer 32 and extend along the horizontal direction, the one being positioned closest to the second semiconductor layer 31 in the thickness direction of the first wiring layer 32. The first wire enables suppression of interposition of another wire between the first wire and the second semiconductor layer 31 and allows suppression of extension of a wiring path between the photoelectric conversion element PD and the first transistor. This enables the effects of the parasitic capacitance to further be suppressed, allowing suppression of an increase in parasitic capacitance of the impedance modulation circuit, suppression of a reduction in voltage signal, and suppression of a reduction in sensitivity of the circuit 3B.

Moreover, in the photodetection device 1 according to the first embodiment of the present technology, the first wiring layer 32 includes the connection pad 32d that is electrically connected to the circuit 3B and faces the surface of the first wiring layer 32 on the second wiring layer 42 side, and the second wiring layer 42 includes the connection pad 42d that is electrically connected to the circuit 3C and faces the surface of the second wiring layer 42 on the first wiring layer 32 side, the connection pad 32d and the connection pad 42d being joined together. Since the connection pads are joined together, even in a case where the circuit 3B and the circuit 3C are provided on different boards, the circuit 3B and the circuit 3C can electrically be connected to each other.

Note that, in the photodetection device 1 according to the first embodiment of the present technology, the wire 32b is provided in the first wiring layer 32 in only one layer along the thickness direction, but a plurality of layers of wire 32b may be provided along the thickness direction. Even in that case, the first wire may be one of the wires that are provided in the first wiring layer 32 and extend along the horizontal direction, the one being positioned closest to the second semiconductor layer 31 in the thickness direction of the first wiring layer 32.

In addition, in a case where a plurality of layers of the wire 32b are provided along the thickness direction of the wire 32b and where a slight increase in parasitic capacitance is acceptable, the first wire need not be the wire 32b positioned closest to the second semiconductor layer 31 in the thickness direction of the first wiring layer 32.

Furthermore, while the first transistors are positioned in the second semiconductor layer 31 closer to the first wiring layer 32, the first transistors may be positioned in the second semiconductor layer 31 closer to the second insulating layer 33 in a case where a slight increase in parasitic capacitance is acceptable. In that case, it is sufficient if the wiring portion of the circuit 3B is modified as appropriate, and for example, the first wire (wire 32b) and the first conductor 32c may be provided in the second insulating layer 33.

### Example of Application to Electronic Equipment

Now, an example will be described in which the present technology is applied to electronic equipment 100 depicted in FIG. 6. The electronic equipment 100 includes a solid-state imaging device 101, the optical lens 102, a shutter device 103, a drive circuit 104, and a signal processing circuit 105. The electronic equipment 100 is, for example, a camera or the like but is not limited to this. In addition, the electronic equipment 100 includes the above-described photodetection device 1 as the solid-state imaging device 101.

The optical lens (optical system) 102 forms image light (incident light 106) from a subject into an image on an imaging surface of the solid-state imaging device 101. Hence, signal charge is accumulated in the solid-state imaging device 101 over a predetermined period of time. The shutter device 103 controls a period of irradiation of the solid-state imaging device 101 with light and a period of shading. The drive circuit 104 feeds drive signals for controlling a transfer operation of the solid-state imaging device 101 and a shutter operation of the shutter device 103. The drive signal (timing signal) fed from the drive circuit 104 is used to transfer signals from the solid-state imaging device 101. The signal processing circuit 105 executes various types of signal processing on the signal (pixel signal) output from the solid-state imaging device 101. A video signal resulting from the signal processing is stored in a storage medium such as a memory or is output to a monitor.

Such a configuration allows the electronic equipment 100 to suppress a reduction in current gain in the solid-state imaging device 101, allowing the quality of an obtained image to be improved.

Note that the electronic equipment 100 is not limited to the camera and may be another piece of electronic equipment. For example, the electronic equipment 100 may be an imaging device such as a camera module for mobile equipment such as a cellular phone.

### Second Embodiment

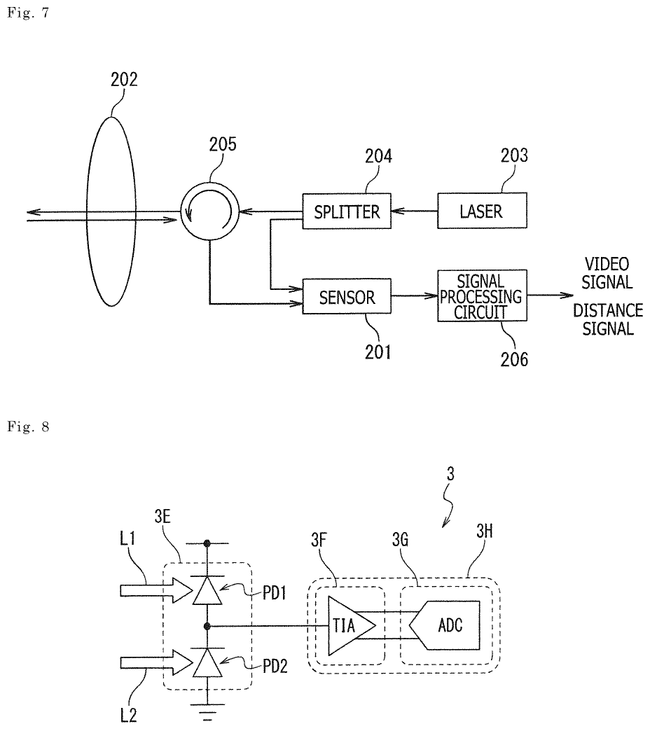

A second embodiment of the present technology depicted in FIG. 7 and FIG. 8 will be described below. The photodetection device 1 according to the present second embodiment has a configuration basically similar to that of the photodetection device 1 according to the first embodiment except that the photodetection device 1 of the second embodiment is equipped with an FMCW (Frequency Modulated Continuous Wave) circuit. Note that the already described components are denoted by the same reference signs, and the description of these components is omitted. In addition, FIG. 4 for the first embodiment is also used to describe the present embodiment.

FIG. 7 is a block diagram depicting an example of a general configuration of electronic equipment 200. The electronic equipment 200 includes a sensor 201, an optical lens 102, a laser 203 that radiates laser light while varying frequency, a splitter 204, a circulator 205, and a signal processing circuit 206. The electronic equipment 200 is, for example, electronic equipment for ranging such as LiDAR (Light Detection and Ranging) but is not limited to this. In addition, the electronic equipment 200 includes, as the sensor 201, the photodetection device 1 for ranging equipped with an FMCW circuit.

The optical lens (optical system) 202 irradiates a subject with laser light (emitted light) radiated by the laser 203 and condenses laser light reflected by the subject as reflected light. The splitter 204 feeds a portion of the laser light radiated by the laser 203, to the circulator 205 as emitted light, while feeding a portion of the laser light to the sensor 201 as emitted light. The circulator 205 feeds the optical lens 202 with the emitted light fed via the splitter 204, while feeding the sensor 201 with the reflected light fed via the optical lens 202. The sensor 201 is fed with both the emitted light and the reflected light. The reflected light has a larger optical path length than the emitted light, and hence, the sensor 201 receives the emitted light and the reflected light at different timings. The signal processing circuit 206 executes various types of signal processing on a signal (pixel signal) output from the sensor 201. A video signal resulting from the signal processing is stored in a storage medium such as a memory or is output to a monitor. In addition, on the basis of the timing when the sensor 201 receives the emitted light and the timing when the sensor 201 receives the reflected light, the signal processing circuit 206 determines a distance to the subject and outputs a distance signal. The distance signal is stored in the storage medium such as a memory or is output to the monitor.

FIG. 8 is an equivalent circuit diagram depicting a configuration example of the pixel 3. More specifically, FIG. 8 depicts a configuration example of the FMCW circuit. The pixel 3 includes a circuit 3E, a circuit 3F succeeding the circuit 3E and connected to the circuit 3E, and a circuit 3G succeeding the circuit 3F and connected to the circuit 3F. A readout circuit 3H includes the circuit 3F and the circuit 3G, a photocurrent from the circuit 3E is input to the readout circuit 3H, and the readout circuit 3H can output a pixel signal.

The circuit 3E includes two photoelectric conversion elements, i.e., a photoelectric conversion element PD1 and a photoelectric conversion element PD2. The photoelectric conversion elements PD1 and PD2 generate signal charge according to the amount of light received. The photoelectric conversion element PD1 receives output light L1 from the laser 203 to generate signal charge. The photoelectric conversion element PD2 receives reflected light L2 from the subject to generate signal charge. Anode sides of the photoelectric conversion elements PD1 and PD2 are connected to an input end of the circuit 3F. The photoelectric conversion elements PD1 and PD2 are, for example, photodiodes. The circuit 3E outputs, as a photocurrent, the signal charge from the anode side corresponding to an output end.

The input end of the circuit 3F (first circuit) is connected to the output end of the circuit 3E, and the photocurrent from the circuit 3E is input to the input end. The circuit 3F is an amplifying circuit. More specifically, the circuit 3F is an impedance modulation circuit that amplifies a photocurrent generated in the photoelectric conversion elements PD and outputs a voltage signal from an output end. In the present embodiment, the voltage output by the circuit 3F is referred to as a voltage signal. Since it is sufficient if the circuit 3F is a known impedance modulation circuit, description of a detailed circuit configuration is omitted. Signal charge Q is converted into a voltage in accordance with V=Q/C. Accordingly, reducing parasitic capacitance C increases the voltage V obtained, allowing sensitivity of the circuit 3F to be increased.

An input end of the circuit 3G (second circuit) is connected to the output end of the circuit 3F, and the voltage signal from the circuit 3F is input to the input end. The circuit 3G includes an analog digital conversion circuit. The analog digital conversion circuit converts an analog value of the voltage signal fed from the circuit 3F, into a digital value. Since it is sufficient if the circuit 3G is a known analog digital conversion circuit, description of a detailed circuit configuration is omitted.

The first semiconductor layer 21 depicted in FIG. 4 is provided with the photoelectric conversion elements PD1 and PD2 of the circuit 3E. More specifically, the first semiconductor layer 21 is provided with the photoelectric conversion elements PD1 and PD2 for each pixel 3. The circuit 3F is provided within the three layers ranging from the insulating layer IF to the first wiring layer 32. All of the transistors (first transistors) included in the circuit 3F are provided in the second semiconductor layer 31. The circuit 3G is provided within the two layers ranging from the second wiring layer 42 to the third semiconductor layer 41. All of the transistors (second transistors) included in the circuit 3G are provided in the third semiconductor layer 41.

### Main Effects of Second Embodiment

Main effects of the second embodiment will be described below. The photodetection device 1 according to the second embodiment produces effects similar to those of the photodetection device 1 according to the first embodiment described above.

In addition, in the photodetection device 1 according to the second embodiment described above, the analog digital conversion circuit of the circuit 3G is provided in the circuit board section different from that in which the impedance modulation circuit of the circuit 3F is provided. Accordingly, a manufacturing process of forming the analog digital conversion circuit can be constructed regardless of a manufacturing process of forming the analog digital conversion circuit. As for the impedance modulation circuit, transistors with large sizes may be designed in order to reduce noise. By providing the impedance modulation circuit and the analog digital conversion circuit in different circuit board sections, a design rule for the analog digital conversion circuit need not be adapted to a design rule for the impedance modulation circuit. Compared to a case where the impedance modulation circuit and the analog digital conversion circuit are provided in the same circuit board section, the present configuration enables a finer analog digital conversion circuit to be provided. Accordingly, compared to the case where the impedance modulation circuit and the analog digital conversion circuit are provided in the same circuit board section, the present configuration enables an increase in gradation for the analog digital conversion circuit, allowing the image quality of obtained images to be improved.

### Third Embodiment

### 1. Example of Application to Mobile Body

The technology according to the present disclosure (present technology) can be applied to various products. For example, the technology according to the present disclosure may be implemented as a device mounted in any type of mobile body such as an automobile, an electric vehicle, a hybrid electric vehicle, a motorcycle, a bicycle, a personal transporter, an airplane, a drone, a ship, or a robot.

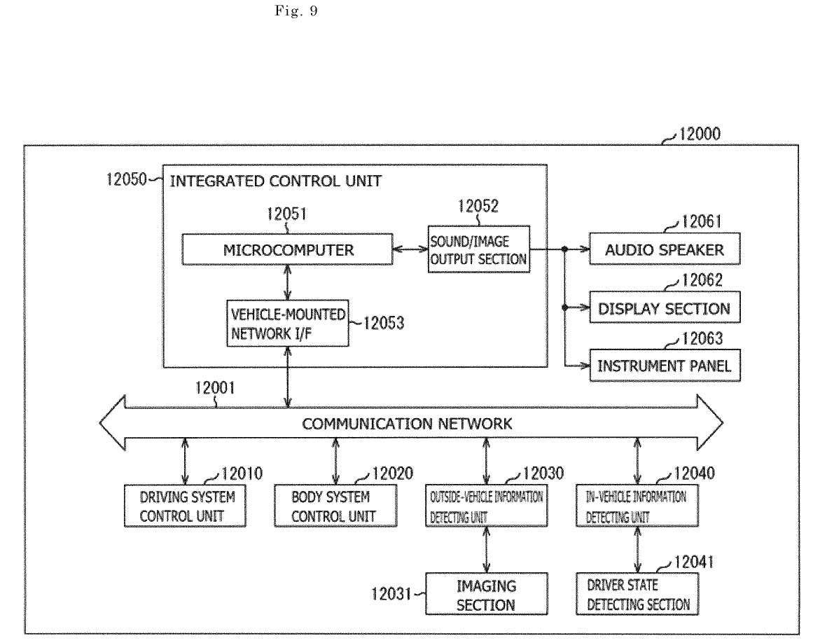

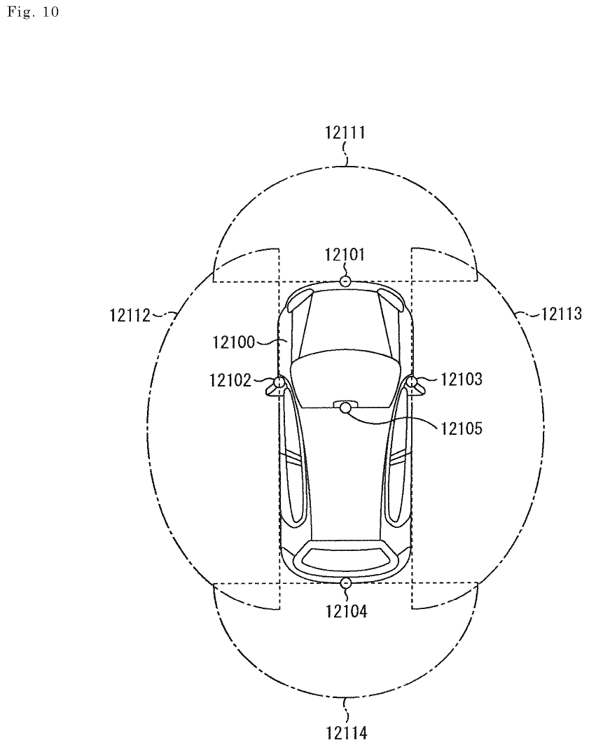

FIG. 9 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 9, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 9, an audio speaker 12061, a display section 12062, and an instrument panel 12063 are illustrated as the output device. The display section 12062 may, for example, include at least one of an on-board display and a head-up display.

FIG. 10 is a diagram depicting an example of the installation position of the imaging section 12031.

In FIG. 10, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 10 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by super-imposing image data imaged by the imaging sections 12101 to 12104, for example.

At least one of the imaging sections 12101 to 12104 may have a function of obtaining distance information. For example, at least one of the imaging sections 12101 to 12104 may be a stereo camera including a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/h). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described. The technology according to the present disclosure can be applied to the imaging section 12031 of the above-described configuration. Specifically, the photodetection device 1 described above can be applied to the imaging section 12031. By applying the technology according to the present disclosure to the imaging section 12031, easier-to-see captured images can be obtained, enabling the fatigue of the driver to be reduced.

### Other Embodiments

The present technology has been described above in conjunction with the first embodiment to the third embodiment. However, the description and drawings of the present disclosure should not be understood as limiting the present technology. From the present disclosure, various alternative embodiments, examples, and operational technologies will be clear to those skilled in the art. For example, the power supply line VDD depicted in FIG. 3 need not be included in the circuit 3B. Further, the circuit 3B depicted in FIG. 3 is a known impedance modulation, more specifically, a known CTIA circuit, and the voltage holding circuit 3C1 of the circuit 3C is a known voltage holding circuit, for example, a known sample hold circuit. Accordingly, on the basis of known circuits, appropriate modifications can be made to the elements of the circuit 3B and the circuit 3C, connections between the elements, roles of the elements, and the like. The circuit 3F and the circuit 3G depicted in FIG. 8 are also known circuits, and hence, on the basis of known circuits, appropriate modifications and settings can be made to the elements of the circuit 3F and the circuit 3G, connections between the elements, roles of the elements, and the like.

In addition, for example, the technical concepts described in the first embodiment to the third embodiment can be combined together. Further, for example, the materials cited as being used for the components described above may contain additives, impurities, and the like. Moreover, for example, a barrier metal layer may be provided in members such as wires including metal materials as described above.

Needless to say, as described above, the present technology includes various embodiments and the like not described herein. Therefore, the technical scope of the present technology is determined only by matters specifying the disclosure, which are recited in the claims and which are valid from the above description.

Furthermore, the effects described herein are merely illustrative and not restrictive, and any other effects may be produced.

Note that the present technology may adopt the following configurations.
(1)

A light detecting device, comprising:
a first section including a first substrate, the first substrate including a compound semiconductor layer configured to convert light into an electrical signal;
a second section including a second substrate, the second substrate including a first amplifying circuit that amplifies the electrical signal; and
a third section including a third substrate, the third substrate including a second amplifying circuit and a selection circuit, wherein the first, second, and third sections are stacked with the second section being between the first section and the third section.
(2)

The light detecting device of (1), wherein the first section further comprises an electrode that transfers the electric signal to the first amplifying circuit.
(3)

The light detecting device of one or more of (1) to (2), wherein the first section includes an insulating layer in which the electrode is disposed.
(4)

The light detecting device of one or more of (1) to (3), wherein the insulating layer is between the first substrate and the second substrate.
(5)

The light detecting device of one or more of (1) to (4), wherein the first amplifying circuit includes a transimpedance amplifier (TIA) circuit.
(6)

The light detecting device of one or more of (1) to (5), wherein the TIA circuit is a capacitive TIA circuit comprising a feedback loop that includes a capacitance.
(7)

The light detecting device of one or more of (1) to (6), wherein the second amplifying circuit comprises an amplification transistor.
(8)

The light detecting device of one or more of (1) to (7), wherein the selection circuit comprises a selection transistor that receives output of the amplification transistor.
(9)

The light detecting device of one or more of (1) to (8), wherein the third substrate further comprises a holding circuit connected to the second amplifying circuit.
(10)

The light detecting device of one or more of (1) to (9), wherein the holding circuit comprises a sample and hold circuit.
(11)

The light detecting device of one or more of (1) to (10), wherein the sample and hold circuit comprises a first branch comprising a first capacitance and a second branch comprising a second capacitance.
(12)

The light detecting device of one or more of (1) to (11), wherein the first section further comprises a first insulating layer, the second section further comprises a second insulating layer and a third insulating layer on opposing sides of the second substrate, and the third section further comprises a fourth insulating layer.
(13)

The light detecting device of one or more of (1) to (12), wherein the first insulating layer and the second insulating layer contact one another at an interface between the first section and the second section.
(14)

The light detecting device of one or more of (1) to (13), wherein the third insulating layer and the fourth insulating layer contact one another at an interface between the second section and the third section.
(15)

A light detecting device, comprising:
a first section including a first substrate, the first substrate including a compound semiconductor layer configured to convert light into an electrical signal;
a second section including a second substrate, the second substrate including a first amplifying circuit that amplifies the electrical signal; and
a third section including a third substrate, the third substrate including a sample and hold circuit, wherein the first, second, and third sections are stacked with the second section being between the first section and the third section.
(16)

The light detecting device of (15), wherein the third section further comprises a second amplifying circuit and a selection circuit.
(17)

The light detecting device of one or more of (15) to (16), wherein the first amplifying circuit comprises a transimpedance amplifier (TIA) circuit and the second amplifying circuit comprises an amplification transistor.
(18)

The light detecting device of one or more of (15) to (17), wherein the first section further comprises an electrode that transfers the electric signal to the first amplifying circuit.
(19)

The light detecting device of one or more of (15) to (18), wherein the first section includes an insulating layer in which the electrode is disposed.
(20)

An electronic device, comprising:
a signal processing circuit; and
a light detecting device, comprising:
a first section including a first substrate, the first substrate including a compound semiconductor layer configured to convert light into an electrical signal;
a second section including a second substrate, the second substrate including a first amplifying circuit that amplifies the electrical signal; and
a third section including a third substrate, the third substrate including a second amplifying circuit and a selection circuit, wherein the first, second, and third sections are stacked with the second section being between the first section and the third section.

The scope of the present technology is not limited to the illustrative embodiments illustrated and described and includes all embodiments producing effects equivalent to those intended by the present technology. Furthermore, the scope of the present technology is not limited to combinations of features of the disclosure determined by the claims and can be determined by all desired combinations of particular ones of all disclosed features.

### REFERENCE SIGNS LIST

1: Photodetection device
2: Semiconductor chip
3: Pixel
3A, 3B, 3C, 3E, 3F, 3G: Circuit
3D, 3H: Readout circuit
3C1: Voltage holding circuit
3C2: Source follower circuit
4: Vertical drive circuit
5: Column signal processing circuit
6: Horizontal drive circuit
7: Output circuit
8: Control circuit
20: Light receiving board section
21: First semiconductor layer
21a: First contact layer
21b: Photoelectric conversion layer
21c: Second contact layer
22: First insulating layer
23: Second electrode
24: Protect film
25: Diffusion region
30: First circuit board section
31: Second semiconductor layer
32: First wiring layer
32b: Wire
32c: First conductor
32d: Connection pad
32e: Second conductor
33: Second insulating layer
40: Second circuit board section
41: Third semiconductor layer
42: Second wiring layer
42d: Connection pad
100: Electronic equipment
101: Solid-state imaging device
102: Optical system (optical lens)
200: Electronic equipment
201: Sensor
202: Optical lens (optical system)
203: Laser
204: Splitter
205: Circulator
206: Signal processing circuit
a, b, c, d, e, f, g, h, i, j: Transistor
Cf: Feedback capacitance
CSH_D, CSH_P: Capacitor

What is claimed is:

1. A light detecting device, comprising:
a first section including a first substrate, the first substrate including a compound semiconductor layer configured to convert light into an electrical signal;
a second section including a second substrate, the second substrate including a first amplifying circuit that amplifies the electrical signal; and
a third section including a third substrate, the third substrate including a second amplifying circuit and a selection circuit, wherein the first, second, and third sections are stacked with the second section being between the first section and the third section.

2. The light detecting device of claim 1, wherein the first section further comprises an electrode that transfers the electric signal to the first amplifying circuit.

3. The light detecting device of claim 2, wherein the first section includes an insulating layer in which the electrode is disposed.

4. The light detecting device of claim 3, wherein the insulating layer is between the first substrate and the second substrate.

5. The light detecting device of claim 1, wherein the first amplifying circuit includes a transimpedance amplifier (TIA) circuit.

6. The light detecting device of claim 5, wherein the TIA circuit is a capacitive TIA circuit comprising a feedback loop that includes a capacitance.

7. The light detecting device of claim 5, wherein the second amplifying circuit comprises an amplification transistor.

8. The light detecting device of claim 7, wherein the selection circuit comprises a selection transistor that receives output of the amplification transistor.

9. The light detecting device of claim 1, wherein the third substrate further comprises a holding circuit connected to the second amplifying circuit.

10. The light detecting device of claim 9, wherein the holding circuit comprises a sample and hold circuit.

11. The light detecting device of claim 10, wherein the sample and hold circuit comprises a first branch comprising a first capacitance and a second branch comprising a second capacitance.

12. The light detecting device of claim 1, wherein the first section further comprises a first insulating layer, the second section further comprises a second insulating layer and a third insulating layer on opposing sides of the second substrate, and the third section further comprises a fourth insulating layer.

13. The light detecting device of claim 12, wherein the first insulating layer and the second insulating layer contact one another at an interface between the first section and the second section.

14. The light detecting device of claim 13, wherein the third insulating layer and the fourth insulating layer contact one another at an interface between the second section and the third section.

15. A light detecting device, comprising:
a first section including a first substrate, the first substrate including a compound semiconductor layer configured to convert light into an electrical signal;
a second section including a second substrate, the second substrate including a first amplifying circuit that amplifies the electrical signal; and
a third section including a third substrate, the third substrate including a sample and hold circuit, wherein the first, second, and third sections are stacked with the second section being between the first section and the third section.

16. The light detecting device of claim 15, wherein the third section further comprises a second amplifying circuit and a selection circuit.

17. The light detecting device of claim 16, wherein the first amplifying circuit comprises a transimpedance amplifier (TIA) circuit and the second amplifying circuit comprises an amplification transistor.

18. The light detecting device of claim 15, wherein the first section further comprises an electrode that transfers the electric signal to the first amplifying circuit.

19. The light detecting device of claim 18, wherein the first section includes an insulating layer in which the electrode is disposed.

20. An electronic device, comprising:
a signal processing circuit; and
a light detecting device, comprising:
a first section including a first substrate, the first substrate including a compound semiconductor layer configured to convert light into an electrical signal;
a second section including a second substrate, the second substrate including a first amplifying circuit that amplifies the electrical signal; and
a third section including a third substrate, the third substrate including a second amplifying circuit and a selection circuit, wherein the first, second, and third sections are stacked with the second section being between the first section and the third section.
